(19) United States
(12) Patent Application Publication
(10) Pub. No.: US 2026/0353982 A1
(43) Pub. Date: Nov. 5, 2026

(54) DISPLAY DEVICE

(71) Applicant: LG Display Co., Ltd., Seoul (KR)

(72) Inventor: JaeWon LIM, Paju-si (KR)

(73) Assignee: LG Display Co., Ltd., Seoul (KR)

(21) Appl. No.: 19/545,832

(22) Filed: Feb. 20, 2026

(30) Foreign Application Priority Data
Apr. 30, 2025 (KR) 10-2025-0057675

(51) Int. Cl. H10K 59/80

(52) U.S. Cl. CPC H10K 59/8722; H10K 59/874

(57) ABSTRACT

A display device can include a first substrate including a display area and a non-display area outside the display area, a plurality of light emitting elements disposed on the first substrate, an adhesive layer disposed on the plurality of light emitting elements and including a plurality of core-shell particles, and a second substrate disposed on the adhesive layer, and the plurality of core-shell particles includes reduced titanium oxide (TiO₂₋ₓ).

### CROSS-REFERENCE TO RELATED APPLICATIONS

This application claims priority to Korean Patent Application No. 10-2025-0057675, filed in the Republic of Korea on Apr. 30, 2025, the entire disclosure of which is hereby expressly incorporated by reference.

### BACKGROUND

### Field

The present disclosure relates to a display device, and more particularly, to a display device capable of preventing or minimizing moisture permeation.

### Discussion of the Related Art

Currently, as the world enters a full-fledged information era, the field of display devices that visually display information is rapidly developing, and research is being conducted to improve performance such as thinning, weight reduction, and low power consumption for various display devices.

Representative display devices can include a liquid crystal display (LCD), an electro-wetting display (EWD), and a light emitting display device such as an organic light emitting display (OLED).

Among these devices, a light emitting display device including an organic light emitting display device is a self-emitting display device, and unlike a liquid crystal display device, a separate light source is not required. As such, the light emitting display device can be manufactured to have a light weight and a small thickness. In addition, the light emitting display device is advantageous in terms of power consumption because the light emitting display device operates at a low voltage. Further, the light emitting display device is expected to be used in various fields because the light emitting display device is excellent in color implementation, response speed, viewing angle, and contrast ratio.

### SUMMARY OF THE DISCLOSURE

An object to be achieved by the present disclosure is to provide a display device with improved moisture and oxygen blocking capabilities.

Another object to be achieved by the present disclosure is to provide a display device with reduced dark spot defects due to aggregation of an oxygen adsorbent.

Still another object to be achieved by the present disclosure is to provide a display device comprising an oxygen adsorbent manufactured at a low cost.

Still another object to be achieved by the present disclosure is to provide a display device in which an oxygen adsorbent is disposed only in an area that may be vulnerable to moisture permeation and oxygen permeation.

Another object to be achieved by the present disclosure is to provide an improved display device, which addresses the limitations and disadvantages associated with the related art.

Objects of the present disclosure are not limited to the above-mentioned objects, and other objects, which are not mentioned above, can be clearly understood by those skilled in the art from the following descriptions.

A display device according to an example embodiment of the present disclosure includes a first substrate including a display area and a non-display area outside the display area, a plurality of light emitting elements disposed on the first substrate, an adhesive layer disposed on the plurality of light emitting elements and including a plurality of core-shell particles, and a second substrate disposed on the adhesive layer. The plurality of core-shell particles includes reduced titanium oxide (TiO₂₋ₓ).

A display device according to another example embodiment of the present disclosure includes a first substrate including a display area and a non-display area outside the display area, a plurality of light emitting elements disposed on the first substrate, an adsorption layer disposed on the plurality of light emitting elements and including a plurality of core-shell particles, and a second substrate disposed on the adsorption layer. Each of the plurality of core-shell particles includes a core particle made of silicon oxide (SiO₂) and a shell layer surrounding the core particle and including oxygen vacancy.

Other detailed matters of the embodiments of the present disclosure are included in the detailed description and the drawings.

Various features of the present disclosure can improve the reliability of moisture permeation and oxygen permeation prevention performance by using an oxygen adsorbent with less aggregation.

The various features of the present disclosure can reduce the manufacturing cost of a display device by using an oxygen adsorbent coated with an oxygen adsorption material on a core particle manufactured at low cost.

According to the features of the present disclosure, the oxygen adsorbent can be disposed only in the outer peripheral area of the display device to effectively reduce the dark spot defect.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIGS. 1A and 1B are plan views of a display device according to an example embodiment of the present disclosure.

FIG. 2 is a cross-sectional view of a sub pixel of a display device according to an embodiment of the present disclosure.

FIG. 3 is a cross-sectional view taken along line A-A' of the display device of FIG. 1A.

FIG. 4 is a plan view of a display device according to another embodiment of the present disclosure.

FIG. 5 is a plan view of a display device according to another embodiment of the present disclosure.

FIG. 6 is a cross-sectional view of a display device according to still another embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, “under”, and “next”, etc., one or more parts can be positioned between the two parts unless the terms are used with the term “immediately” or “directly”.

When an element or layer is disposed “on” another element or layer, another layer or another element can be interposed directly on the other element or therebetween.

Although the terms such as “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other. Further, the term “can” fully encompasses all the meanings and coverages of the term “may” and vice versa.

Hereinafter, various embodiments of the present disclosure will be described in detail with reference to the accompanying drawings. All the components of each display device/apparatus according to all embodiments of the present disclosure are operatively coupled and configured.

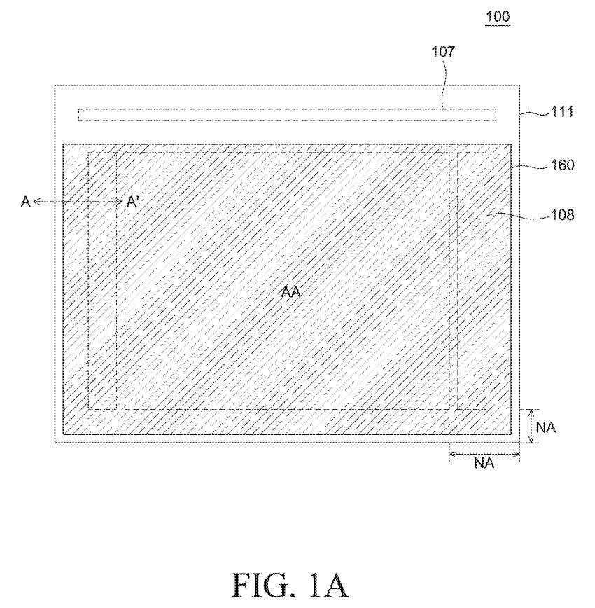

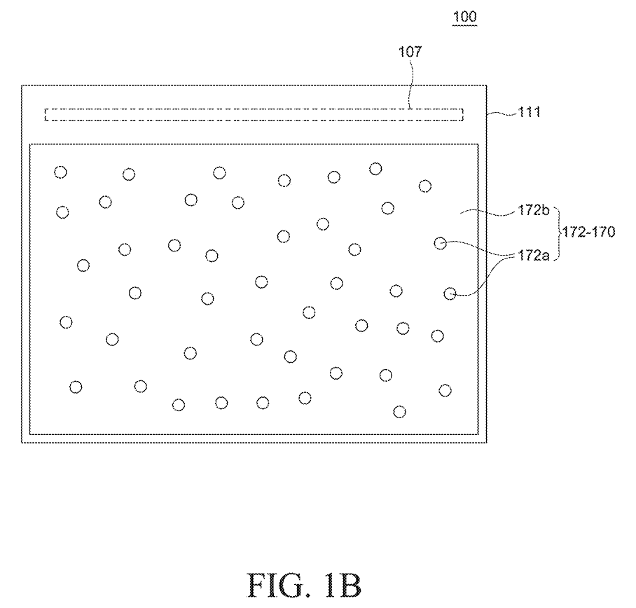

FIGS. 1A and 1B are plan views of a display device according to an example embodiment of the present disclosure. FIG. 1B is a plan view of a display device 100 in which a second substrate 160 is not shown in a plan view of the display device 100 of FIG. 1A.

Referring to FIGS. 1A and 1B, the display device 100 according to an example embodiment of the present disclosure can include a first substrate 111, a second substrate 160, an adhesive layer 170, and pad parts 107 and 108. The display device 100 is a device for displaying an image to a user.

The display device 100 can include a display element for displaying images, a driving element for driving the display element, and line lines for transmitting various signals to the display element and the driving element. The display element can be differently defined depending on the type of the display device 100, and for example, when the display device 100 is an organic light emitting display device, the display element can be an organic light emitting element including an anode, an organic emission layer, and a cathode. For example, when the display device 100 is a liquid crystal display device, the display element can be a liquid crystal display element.

Hereinafter, even though it is assumed that the display device 100 is an organic light emitting display device, the display device 100 is not limited to the organic light emitting display device and can be a different type of display device.

The display device 100 can include a display area AA (or active area) and a non-display area NA (or non-active rea). The display area AA is an area in which images are displayed in the display device 100.

In the display area AA, a plurality of sub pixels constituting a plurality of pixels and a plurality of circuits for driving the plurality of sub pixels can be disposed. The plurality of sub pixels is minimum units constituting the display area AA, and a display element can be disposed in each of the plurality of sub pixels, and the plurality of sub pixels can constitute a pixel. For example, an organic light emitting element including an anode, an organic emission layer, and a cathode can be disposed in each of the plurality of sub pixels, but it is not limited thereto. Further, a circuit for driving the plurality of sub pixels can include a driving element, a line, and the like. For example, the circuit can be formed of a thin film transistor, a storage capacitor, a gate line, a data line, or the like, but is not limited thereto.

The non-display area NA is an area where no image is displayed. The non-display area NA can surround the display area entirely or only in one or more part(s).

FIG. 1A illustrates that the non-display area NA surrounds the display area AA having a quadrangular shape. However, the shapes and arrangements of the display area AA and the non-display area NA are not limited to the example illustrated in FIG. 1A.

In other words, the display area AA and the non-display area NA can have shapes suitable for the design of an electronic device equipped with the display device 100. For example, an example shape of the display area AA can be a pentagon, a hexagon, a circle, or an oval.

In the non-display area NA, various line lines and circuits for driving the organic light emitting element of the display area AA can be disposed. For example, in the non-display area NA, link lines for transmitting signals to the plurality of sub pixels and circuits of the display area AA, driving integrated circuits (ICs) such as gate driver ICs and data driver ICs or pad parts 107 and 108 can be disposed, but are not limited thereto.

The display device 100 can include various additional elements for generating various signals or driving pixels in the display area AA. The additional elements for driving the pixels can include an inverter circuit, a multiplexer, an electrostatic discharge (ESD) circuit, and the like. The display device 100 can also include additional elements related to functions other than pixel driving. For example, the display device 100 can include additional elements that provide a touch sensing function, a user authentication function (e.g., fingerprint recognition), a multi-level pressure sensing function, a tactile feedback function, and the like. The above-mentioned additional elements can be located in the non-display area NA and/or an external circuit connected to the connection interface.

The pad parts 107 and 108 can be disposed to receive a signal from the outside.

The pad parts 107 and 108 can be disposed in the non-display area NA of the display device 100 to be electrically connected to various line lines and printed circuit boards disposed in the display area AA.

For example, the pad parts 107 and 108 can function to transmit a signal to each of the gate line and the data line, and include a gate pad part 108 to transmit a gate signal to the gate line and a data pad part 107 to transmit a data signal to the data line, but are not limited thereto.

The gate pad unit 108 can be disposed on at least one side of the display device 100, for example, in the non-display area NA on the first side of the display device 100, but is not limited thereto. For example, the first side can mean one of the left and right sides of the display device 100 adjacent to the upper and lower sides.

The data pad unit 107 can be disposed in the non-display area NA on the other side of the display device 100, for example, the second side of the display device 100, but is not limited thereto. For example, the second side can mean an upper side of the display device 100. However, the present disclosure is not limited thereto, and each side surface portion of the non-display area NA can be referred to as at least any one of the first, second, third, and fourth sides.

For example, the data pad unit 107 can be electrically connected to a data driver to supply a data voltage to a plurality of data lines. The data driver can receive image data from the timing controller and supply a data voltage to the plurality of data lines to drive the plurality of data lines. The data driver can be implemented by including one or more source driver integrated circuits.

For example, each source driver integrated circuit can include a shift register, a latch circuit, a digital to analog converter (DAC), an output buffer, and the like. The data driver can further include one or more analog to digital converters (ADCs), in some cases.

Meanwhile, the gate driver can drive a plurality of gate lines by outputting a scan signal to the plurality of gate lines. For example, the gate driver can sequentially drive the plurality of gate lines by sequentially supplying scan signals to the plurality of gate lines. The gate driver can sequentially supply an on voltage or an off voltage scan signal to the plurality of gate lines under the control of the timing controller.

The gate driver can include a plurality of gate driving circuits. Here, the plurality of gate driving circuits can correspond to the plurality of gate lines, respectively.

For example, each gate driving circuit can include a shift register, a level shifter, and the like.

Each gate driving circuit can be implemented in a gate-in-panel (GIP) type and embedded in the display device 100. For example, each gate driving circuit can be directly disposed on the gate pad unit 108, and in this case, the gate pad unit 108 can be referred to as a GIP circuit part.

Referring to FIGS. 1A and 1B, an adhesive layer 170 and a second substrate 160 can be disposed in the display area AA and the non-display area NA of the display device 100. The adhesive layer 170 and the second substrate 160 can overlap an entire surface of the display area AA, and can overlap only a partial area of the non-display area NA surrounding the display area AA. For example, the adhesive layer 170 and the second substrate 160 can overlap the non-display area NA and an entire surface of the display area AA except for the data pad unit 107, but are not limited thereto.

Referring to FIG. 1B, the adhesive layer 170 can include a transparent layer and an adsorption layer 172 disposed on the transparent layer. The adsorption layer 172 can include a resin 172b and a plurality of moisture adsorbents 172a dispersed in the resin 172b. At this time, a plurality of moisture adsorbents 172a can be disposed so as to correspond to the entire surface of the first substrate 111.

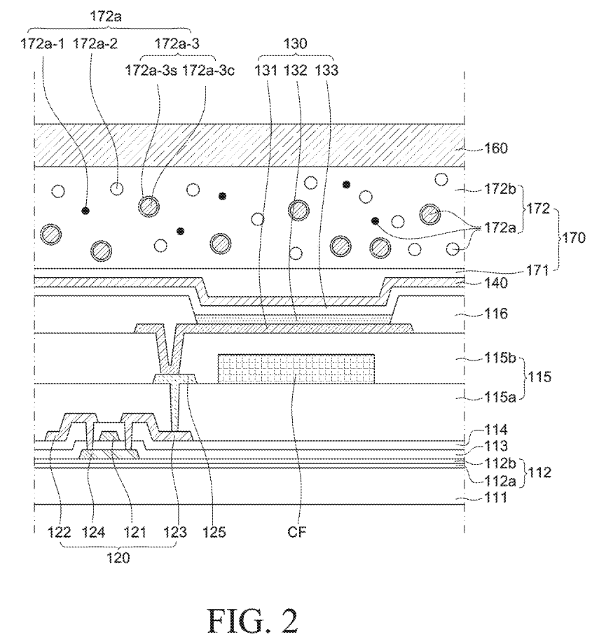

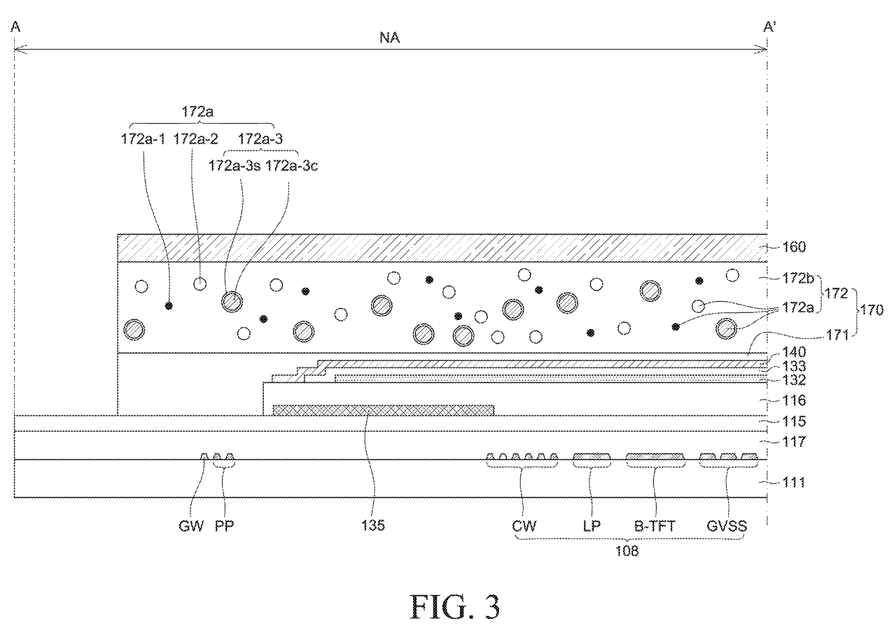

Hereinafter, the adhesive layer 170 will be described in detail with reference to FIGS. 2 and 3.

FIG. 2 is a cross-sectional view of a sub pixel of a display device according to an embodiment of the present disclosure. FIG. 3 is a cross-sectional view taken along line A-A' of the display device of FIG. 1A. For instance, FIG. 3 is a cross-sectional view of a non-display area NA of a first side of a display device 100 of FIG. 1A. Each sub pixel or one or more sub pixels in the display device of the present disclosure according to any of the figures or any embodiment disclosed herein can have the sub pixel configuration shown in FIG. 2 or the like.

For the convenience of description, at least some of the buffer layer 112, the gate insulating layer 113, and the interlayer insulating layer 114 illustrated in FIG. 2 are illustrated as insulating layers 117 in FIG. 3.

The first substrate 111 can be a glass or plastic substrate. In the case of a plastic substrate, a polyimide-based or polycarbonate-based material can be used to have flexibility. In particular, polyimide is a material that can be applied to a high-temperature process and is a material that is well suited for coating processes, so it is widely used as a plastic substrate. A buffer layer 112 can be disposed on the first substrate 111.

Meanwhile, light shielding layer can be disposed on the first substrate 111 to block light introduced from a lower portion of the first substrate 111.

A light shielding layer can be disposed on the first substrate 111 at a position where the active layer 124 is to be formed. In particular, it is preferable that the size of the light shielding layer is slightly larger so as to completely cover the active layer 124.

The buffer layer 112 can be disposed on the entire surface of the first substrate 111 on which the light shielding layer is formed.

The buffer layer 112 is a layer for protecting various electrodes and lines from impurities such as alkali ions discharged from the first substrate 111 or layers therebelow. The buffer layer 112 can have a multilayer structure including a first buffer layer 112a and a second buffer layer 112b, but is not limited thereto. For example, the buffer layer 112 can be made of silicon oxide (SiOₓ), silicon nitride (SiNₓ), or a multi-layer thereof.

The buffer layer 112 can delay diffusion of moisture and/or oxygen permeating the first substrate 111. In addition, the buffer layer 112 can include a multi-buffer and/or an active buffer. The active buffer protects the active layer 124 made of the semiconductor of the driving element 120 and can perform a function of blocking various types of defects introduced from the first substrate 111. The active buffer can be formed of amorphous silicon (a-Si) or the like.

Meanwhile, in the non-display area NA, various line lines and circuits for driving the light emitting element 130 of the display area AA can be disposed. For example, in the non-display area NA, link lines for transmitting signals to the plurality of sub pixels and circuits of the display area AA, driving ICs such as gate driver ICs and data driver ICs or pad parts 107 and 108 can be disposed, but are not limited thereto.

For example, referring to FIG. 3, the ground line GW can be disposed on the first substrate 111 in the non-display area NA.

The ground line GW can be disposed at the edge of the non-display area NA except for the second side. For example, the ground line GW can be disposed in the non-display area NA excluding the upper side of the display device 100, but is not limited thereto.

The ground line GW can be formed of a material constituting the light shielding layer and/or the driving element 120 of the display area AA, but is not limited thereto.

A light blocking pattern PP can be disposed inside of the ground line GW. The light blocking pattern PP can also be disposed in the non-display area NA of the third side, for example, the non-display area NA under the display device 100, but is not limited thereto.

The light blocking pattern PP can be formed of a material constituting the light shielding layer and/or the driving element 120 of the display area AA, but is not limited thereto.

Referring to FIG. 3, the GIP circuit part 108 can be disposed inside the light blocking pattern PP. For example, the GIP circuit part 108 can be disposed in the non-display area NA on the first side, for example, the non-display area NA on the left and right sides of the display device 100.

The GIP circuit part 108 can include a control signal clock line CW, a logic unit LP, a buffer TFT unit B-TFT, and a power line GVSS, but is not limited thereto.

The control signal clock line CW, the logic unit LP, the buffer TFT unit B-TFT, and the power line GVSS can be sequentially disposed from the edge of the second substrate 160, but the present disclosure is not limited thereto.

In this case, the control signal clock line CW, the logic unit LP, the buffer TFT unit B-TFT, and the power line GVSS can be formed of a material constituting the light shielding layer and/or the driving element 120 of the display area AA, but are not limited thereto.

Meanwhile, a link line can be disposed above the first substrate 111 in the non-display area NA on the second side, and a high potential power line can be disposed in the non-display area NA on the third side. For example, a link line can be disposed in the non-display area NA above the display device 100 and a high potential power line can be disposed in the non-display area NA below the display device 100, but the present disclosure is not limited thereto.

The link line and the high potential power line can be formed of a material constituting the light shielding layer and/or the driving element 120 of the display area AA, but the present disclosure is not limited thereto.

Referring to FIG. 2, the driving element 120 can be disposed on the buffer layer 112.

The driving element 120 can include an active layer 124, a gate insulating layer 113, a gate electrode 121, an interlayer insulating layer 114, a source electrode 122, and a drain electrode 123. Further, the driving element 120 can be electrically connected to the light emitting element 130 through the connection electrode 125 to transmit a current or a signal to the light emitting element 130. In addition to the illustrated top gate structure, the driving element 120 can be applied in various ways, such as a bottom gate in which the gate electrode is located below the active layer and a coplanar structure in which the gate electrode, the source electrode, and the drain electrode are disposed on the same plane.

The active layer 124 can be disposed on the buffer layer 112. The active layer 124 can be made of polysilicon (p-Si), and in this case, a predetermined area can be doped with impurities. Further, the active layer 124 can be made of amorphous silicon (a-Si) and can be made of an organic semiconductor material such as pentacene. Further, the active layer 124 can be formed of an oxide semiconductor.

The gate insulating layer 113 can be disposed on the active layer 124. For example, the gate insulating layer 113 can be formed of an insulating inorganic material such as silicon oxide (SiOₓ) or silicon nitride (SiNₓ), or an insulating organic material.

The gate electrode 121 can be disposed on the gate insulating layer 113. For example, the gate electrode 121 can be made of various conductive materials, such as magnesium (Mg), aluminum (Al), nickel (Ni), chromium (Cr), molybdenum (Mo), tungsten (W), gold (Au), or an alloy thereof.

The interlayer insulating layer 114 can be disposed on the gate electrode 121. For example, the interlayer insulating layer 114 can be formed of an insulating material such as silicon oxide (SiOₓ) or silicon nitride (SiNₓ), or an insulating organic material.

A contact hole through which the source and drain areas are exposed can be formed by selective removal of the gate insulating layer 113 and the interlayer insulating layer 114. The source electrode 122 and the drain electrode 123 can be formed on the interlayer insulating layer 114 in a single layer or a multi-layered structure using an electrode material.

If necessary or desired, an additional protective layer made of an inorganic insulating material can be formed to cover the source electrode 122 and the drain electrode 123.

Meanwhile, at least some of the buffer layer 112, the gate insulating layer 113, and the interlayer insulating layer 114, i.e., the insulating layer 117, can extend to the non-display area NA.

The planarization layer 115 can be disposed on the driving element 120 configured as described above.

The planarization layer 115 can have a multilayer structure including at least two layers. For example, referring to FIG. 2, the planarization layer 115 can include a first planarization layer 115a and a second planarization layer 115b, but is not limited thereto.

For example, the first planarization layer 115a is disposed to cover the driving element 120 and can be disposed to expose a part of the source electrode 122 or the drain electrode 123 of the driving element 120.

The planarization layer 115 can extend to the non-display area NA.

The planarization layer 115 can be an overcoat layer, but is not limited thereto.

A connection electrode 125 for electrically connecting the driving element 120 and the light emitting element 130 can be disposed on the first planarization layer 115a. In addition, referring to FIG. 2, various metal layers serving as wires/electrodes such as data lines and signal lines can be disposed on the first planarization layer 115a.

A color filter CF can be disposed on the first planarization layer 115a, but is not limited thereto, and the color filter CF can be deleted depending on the type of the light emitting element 130.

The color filter CF of each sub pixel can have any one of red, green, and blue colors. In addition, in the case of a sub pixel in which white is implemented, the color filter CF may not be disposed. The arrangement of red, green, and blue can be variously formed, and a black matrix capable of absorbing external light can be provided between the color filters CF.

In the case of the bottom emission type, the color filter CF can be located under the anode 131.

Further, a second planarization layer 115b can be disposed on the first planarization layer 115a and the connection electrode 125. The planarization layer 115 according to an example embodiment of the present disclosure can be composed of two layers because the number of signal lines increase as the display device 100 achieves high resolution. Accordingly, since it becomes difficult to dispose all lines on a single layer while securing a minimum spacing therebetween, an additional layer can be introduced. By introducing such an additional layer (i.e., the second planarization layer 115b), greater flexibility in signal line arrangement can be achieved, thereby facilitating the layout design of signal lines and electrodes. In addition, when a dielectric material is used as the planarization layer 115 configured as a multilayer, it can be used for forming capacitance between metal layers.

The second planarization layer 115b can be formed to expose a part of the connection electrode 125. Further, the drain electrode 123 of the driving element 120 and the anode 131 of the light emitting element 130 can be electrically connected by the connection electrode 125.

Meanwhile, referring to FIG. 3, the low potential power line 135 can be disposed on the planarization layer 115. The low potential power line 135 can be disposed over the non-display area NA excluding the second side of the display device 100, for example, the non-display area NA on the left, right, and lower sides, but is not limited thereto.

A bank 116 can be formed in the remaining area excluding the emission area on the planarization layer 115. For example, the bank 116 has a bank hole exposing the anode 131 corresponding to the emission area. The bank 116 can be made of an inorganic insulating material such as silicon nitride (SiNₓ) or silicon oxide (SiOₓ), or an organic insulating material such as BCB, acrylic resin, or imide resin.

The bank 116 can extend to the non-display area NA. For example, the bank 116 can extend to the non-display area NA to cover upper and side surfaces of the low potential power line 135.

Referring back to FIG. 2, the light emitting element 130 can be disposed on the bank 116.

The light emitting element 130 can be configured such that the anode 131, a plurality of organic layers 132, and the cathode 133 are sequentially disposed. For example, the light emitting element 130 can include an anode 131 disposed on the planarization layer 115, the plurality of organic layers 132 disposed on the anode 131, and a cathode 133 disposed on the plurality of organic layers 132.

The display device 100 can be a top emission type or a bottom emission type. In the top emission method, a reflective layer made of an opaque conductive material having high reflectivity, for example, silver (Ag), aluminum (Al), gold (Au), molybdenum (Mo), tungsten (W), chromium (Cr), or an alloy thereof, can be added under the anode 131 so that light emitted from the plurality of organic layers 132 is reflected by the anode 131 and directed upward, for example, in the direction of the cathode 133 at the top. Conversely, in the case of the bottom emission type, the anode 131 can be made of only a transparent conductive material such as indium tin oxide (ITO), indium zinc oxide (IZO), indium gallium zinc oxide (IGZO). Hereinafter, the description will be made on the assumption that the display device 100 of the present disclosure is a bottom emission type. However, the present disclosure is not limited thereto.

The plurality of organic layers 132 can be disposed on the anode 131 exposed by the bank 116. The plurality of organic layers 132 can include an emission layer, an electron injection layer, an electron transport layer, a hole transport layer, a hole injection layer, and the like.

Referring to FIG. 3, the organic layer 132 can extend to the non-display area NA. The plurality of organic layers 132 extends to the non-display area NA, and its edge can be disposed inside compared to the edge of the bank 116, but is not limited thereto.

Referring to FIG. 2, the cathode 133 can be disposed on the plurality of organic layers 132.

In the case of the top emission type, the cathode 133 can include a transparent conductive material. For example, the cathode 133 can be formed of indium tin oxide (ITO), indium zinc oxide (IZO), indium gallium zinc oxide (IGZO), or the like. In the case of the bottom emission type, the cathode 133 can include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 can be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

Referring to FIG. 3, the cathode 133 can extend to the non-display area NA. The cathode 133 can cover a top surface, a side surface, and a top surface of the bank 116 of the organic layer 132 in the non-display area NA, but is not limited thereto.

A capping layer can be disposed on the cathode 133. The capping layer can be formed of a material having a high refractive index and a high light absorption rate to reduce diffused reflection of external light.

The protective layer 140 can be disposed on the light emitting element 130 configured as described above.

The protective layer 140 can be an inorganic layer, and in this case, can be made of silicon oxide (SiOₓ), silicon nitride (SiNₓ), or a multi-layer thereof.

The protective layer 140 can extend to the non-display area NA.

Further, the protective layer 140 can be disposed to surround the cathode 133 except for the non-display area NA on the second side, for example, the non-display area NA disposed on the upper side.

For example, the protective layer 140 can be made of an inorganic insulating material.

The protective layer 140 can delay moisture permeation at the top and suppress the occurrence of defects due to dents or foreign substances.

The protective layer 140 can be made of silicon oxide (SiOₓ), silicon nitride (SiNₓ), or a multi-layered structure thereof to delay moisture permeation, but is not limited thereto.

The adhesive layer 170 and the second substrate 160 can be disposed on the protection layer 140.

However, the present disclosure is not limited thereto, and an encapsulation structure of a multilayer structure composed of a sealing member and a reinforcing substrate can be disposed on the protection layer 140.

The adhesive layer 170 can be disposed between the protective layer 140 and the second substrate 160.

For example, the adhesive layer 170 can serve to delay lateral moisture permeation.

The adhesive layer 170 can include a transparent layer 171 and an adsorption layer 172 on the transparent layer 171.

The transparent layer 171 can enhance the adhesion between the adsorption layer 172 and the lower component positioned under the transparent layer 171. The transparent layer 171 can be disposed so as to correspond to the entire surface of the first substrate 111, but is not limited thereto.

The transparent layer 171 can be made of a resin-based material made of a transparent material. For example, the transparent layer 171 can be made of a material such as isobutyl rubber resin, but is not limited thereto.

The adsorption layer 172 is disposed on the transparent layer 171 and can adsorb or remove moisture or oxygen flowing into the adsorption layer 172.

The adsorption layer 172 includes a plurality of moisture adsorbents 172a and a resin 172b.

The plurality of moisture adsorbents 172a can be a reactive adsorbent that chemically reacts with moisture or oxygen introduced into the adhesive layer 170 to adsorb moisture or oxygen, or can be a physical adsorbent. In this case, the plurality of moisture adsorbents 172a can be disposed so as to correspond to the entire surface of the adhesive layer 170. In addition, the moisture adsorbent 172a can be disposed to overlap the entire surface of the transparent layer 171, but is not limited thereto.

The plurality of moisture adsorbents 172a can include a plurality of hydrogen adsorption particles 172a-1, a plurality of moisture adsorption particles 172a-2, and a plurality of core-shell particles 172a-3.

The plurality of hydrogen adsorption particles 172a-1 can adsorb hydrogen. For example, the organic layer 132 can react with moisture to generate hydrogen, which can cause a white spot phenomenon. Accordingly, the plurality of hydrogen adsorption particles 172a-1 adsorb hydrogen generated due to the organic layer 132 and moisture, thereby preventing or minimizing a white spot phenomenon. The plurality of hydrogen adsorption particles 172a-1 can be formed of, for example, nickel (Ni) particles, but is not limited thereto.

The plurality of moisture adsorption particles 172a-2 can collect moisture introduced from the outside through a physical or chemical reaction. For example, the plurality of moisture adsorption particles 172a-2 can be formed of a plurality of calcium oxide (CaO) particles, but is not limited thereto.

The plurality of core-shell particles 172a-3 can adsorb or remove moisture or oxygen introduced from the outside through a physical or chemical reaction. Each of the plurality of core-shell particle 172a-3 can include a core particle 172a-3c and a shell layer 172a-3s surrounding the core particle 172a-3c.

The core particle 172a-3c has good adhesion to the shell layer 172a-3s and can be made of a material that is stable at high temperatures. For example, the core particles 172a-3c can be made of silicon oxide (SiO₂), but are not limited thereto.

The shell layer 172a-3s collects oxygen introduced into the adhesive layer 170 to prevent or minimize oxygen from penetrating into the lower portion of the adhesive layer 170. For example, the shell layer 172a-3s can be formed of reduced titanium oxide (TiO₂) including oxygen vacancy. However, the present disclosure is not limited thereto. The shell layer 172a-3s is made of one or more metal materials among titanium (Ti), chromium (Cr), vanadium (V), manganese (Mn), zirconium (Zr), niobium (Nb), molybdenum (Mo), technetium (Tc), ruthenium (Ru), rhodium (Rh), and palladium (Pd), and can be made of metal oxide including oxygen vacancy.

The resin 172b can be made of a resin-based material made of a transparent material. For example, the resin 172b can be made of a material such as isobutyl rubber resin, but is not limited thereto.

The second substrate 160 can be disposed on the adhesive layer 170.

The second substrate 160, together with the adhesive layer 170, can protect the light emitting element 130 from external moisture, oxygen, impact, and the like.

For example, the second substrate 160 can serve to prevent or minimize front moisture penetration.

For example, the second substrate 160 can be made of steel use stainless (SUS) or Invar, but is not limited thereto. At this time, Invar is one of the alloys consisting of nickel and iron, and has a very low coefficient of thermal expansion and is relatively stable against temperature changes.

The display device includes an adhesive layer including a plurality of moisture adsorbents to prevent or minimize and delay moisture permeation. For example, the display device can include an adhesive layer in which the reduced metal oxide is dispersed to reduce a dark spot defect of the display device due to moisture permeation.

In the display device 100 according to the example embodiment of the present disclosure, as a moisture adsorbent for adsorbing or removing moisture or oxygen, a plurality of core-shell particles 172a-3 made of reduced metal oxide is used. For example, each of the plurality of core-shell particles 172a-3 can be made of core particles 172a-3c made of silicon oxide (SiO₂) and a shell layer 172a-3s made of reduced titanium oxide (TiO₂₋ₓ). Since the core-shell particles 172a-3 are formed of titanium oxide (TiO₂) including oxygen vacancy, oxygen that has penetrating into the lower component of the adhesive layer 170 can be adsorbed into the core-shell particles 172a-3. Accordingly, moisture or oxygen can be prevented or minimized from penetrating into the lower component of the adhesive layer 170. Accordingly, it is possible to improve the reliability of the display device 100 by delaying the dark spot defect of the display device 100 due to moisture permeation.

Further, in the display device 100 according to the example embodiment of the present disclosure, silicon oxide (SiO₂) having low cost and high adhesion to the shell layer 172a-3s is used as the core particles 172a-3c of the core-shell particles 172a-3, which can reduce the manufacturing cost of the display device 100. Further, the shell layer 172a-3s can be formed by performing an atomic layer deposition (ALD) process on the plurality of core particles 172a-3c. Accordingly, since the core-shell particles 172a-3 in a particle state can be formed by an ALD process without a separate process of forming particles, the manufacturing process of the display device 100 can be reduced.

Furthermore, in the display device 100 according to the example embodiment of the present disclosure, titanium oxide (TiO₂) having a small particle size is used as the shell layer 172a-3s of the core-shell particles 172a-3. Accordingly, an excessive increase in size due to the aggregation phenomenon of the core-shell particles 172a-3 can be prevented, and damage to the light emitting element 130 can be reduced. Accordingly, dark-spot defects of the display device 100 can be reduced, and reliability can be improved.

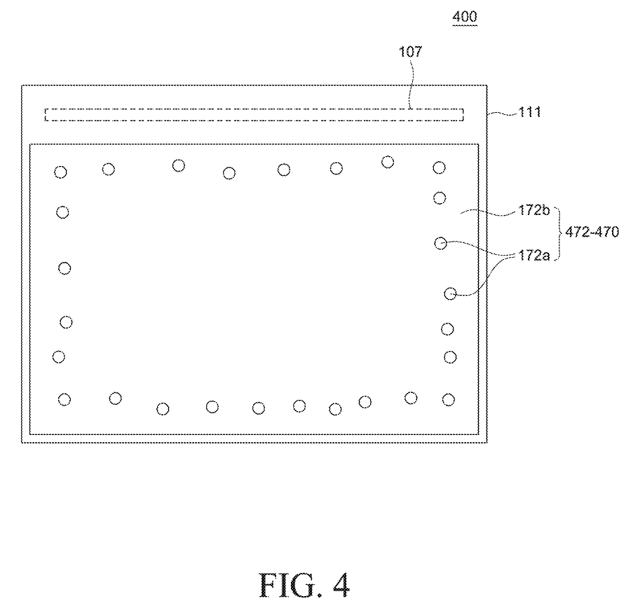

FIG. 4 is a plan view of a display device according to another embodiment of the present disclosure. A display device 400 of FIG. 4 is different from the display device 100 of FIGS. 1A - 3 only or mainly in an adsorption layer 472 of an adhesive layer 470, so that a redundant description will be omitted or may be briefly provided. In FIG. 4, for the convenience of description, the second substrate 160 is not illustrated.

Referring to FIG. 4, the adsorption layer 472 of the adhesive layer 470 is disposed on the first substrate 111.

The adsorption layer 472 can include a resin 172b and a plurality of moisture adsorbents 172a dispersed in the resin 172b.

The plurality of moisture adsorbents 172a can include a plurality of hydrogen adsorption particles, a plurality of moisture adsorption particles, and a plurality of core-shell particles. Each of the plurality of hydrogen adsorption particles, the plurality of moisture adsorption particles, and the plurality of core-shell particles of the display device 400 of FIG. 4 is substantially the same as each of the plurality of hydrogen adsorption particles 172a-1, the plurality of moisture adsorption particles 172a-2, and the plurality of core-shell particles 172a-3 of the display device 100 of FIGS. 1A - 3, and thus, a redundant description will be omitted or may be briefly provided.

At this time, the plurality of moisture adsorbents 172a can be disposed so as to correspond to an outer peripheral area of the first substrate 111. For example, the plurality of moisture adsorbents 172a can be disposed only in the outer portion of the adsorption layer 472, among the central portion of the adsorption layer 472 and the outer portion surrounding the central portion.

In the display device 400 according to another example embodiment of the present disclosure, as a moisture adsorbent for adsorbing or removing moisture or oxygen, a plurality of core-shell particles 172a-3 made of reduced metal oxide is used. For example, titanium oxide (TiO₂) comprising oxygen vacancy is used as the shell layer 172a-3s of a plurality of core-shell particles 172a-3c, and silicon oxide (SiO₂) having low cost and high adhesion to the shell layer 172a-3s is used as the core particles 172a-3c. Accordingly, a dark spot defect of the display device 400 due to moisture permeation can be delayed by using a plurality of low-cost core-shell particles 172a-3.

Further, in the display device 400 according to another example embodiment of the present disclosure, since titanium oxide (TiO₂) having a small particle size is used as the shell layer 172a-3s of the core-shell particles 172a-3, an excessive increase in size due to the aggregation phenomenon of the core-shell particles 172a-3 can be prevented, and damage to the light emitting element 130 can be reduced.

Further, in the display device 400 according to another example embodiment of the present disclosure, the plurality of core-shell particles 172a-3 is disposed only in the outer portion of the adsorption layer 472, among the central portion of the adsorption layer 472 and the outer portion surrounding the central portion. Moisture and oxygen can penetrate into the inside from the outer portion of the display device 400. Accordingly, in the display device 400 according to another example embodiment of the present disclosure, the plurality of core-shell particles 172a-3 is disposed only at the outer portion of the adsorption layer 472, which is an area vulnerable to moisture permeation and oxygen permeation, to effectively prevent or minimize moisture permeation and oxygen permeation.

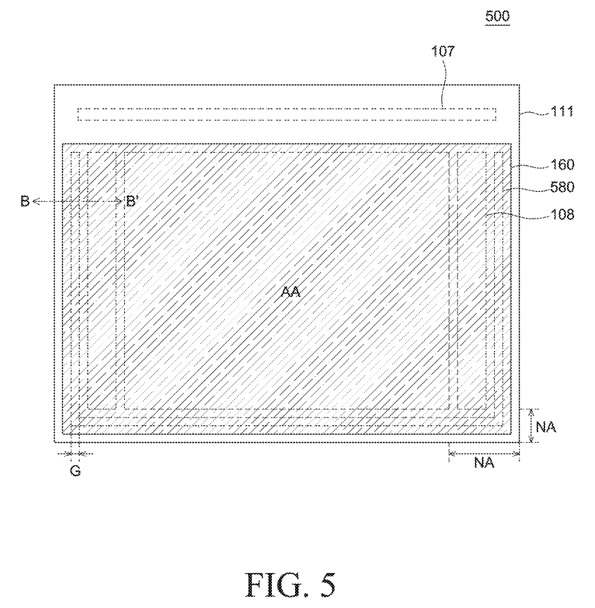

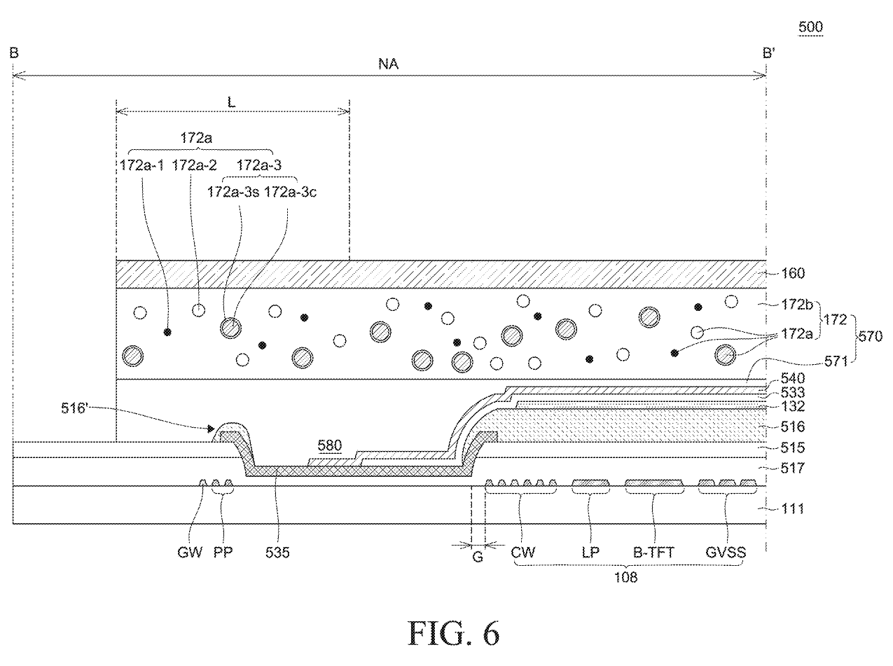

FIG. 5 is a plan view of a display device according to another embodiment of the present disclosure. FIG. 6 is a cross-sectional view of a display device according to still another embodiment of the present disclosure. In the display device 500 of FIGS. 5 and 6, a trench 580 and an outer bank 516′ are added in comparison with the display device 100 of FIGS. 1A - 3, and only a low potential power line 535, an insulating layer 517, a planarization layer 515, a bank 516, a cathode 533, a protective layer 540, and a transparent layer 571 are different from each other, so that a redundant description will be omitted or may be briefly provided.

Referring to FIGS. 5 and 6, the trench 580 can be provided at the edge of the non-display area NA. The trench 580 is an area in which the insulating layer 517 and the planarization layer 515 are removed. In this case, the trench 580 can be disposed to be spaced apart from the GIP circuit portion 108 by a predetermined interval G. Accordingly, the effect of moisture permeation on the GIP circuit part 108 can be minimized.

The trench 580 can be formed over the second side in which the data pad unit 107 is disposed, for example, the non-display area NA on the left, right, and lower sides excluding the upper side, among the four side portions of the display device 500, but is not limited thereto.

The trench 580 can be disposed in a shadow area in the non-display area NA. Accordingly, the reliability bezel area L can be expanded by converting the existing shadow area into the reliability bezel area L, and the width of the bezel can be reduced by the length of the added reliability bezel area L. Accordingly, the trench 580 can delay the moisture penetration rate to the side surface of the display device 500. In this case, the reliability bezel area L can be defined as an end portion of the second substrate 160 to an end portion of the cathode 533.

Referring to FIG. 6, the low potential power line 535 can be disposed in the trench 580. Further, the low potential power line 535 can be disposed to cover upper and side surfaces of the insulating layer 517 and the planarization layer 515 exposed by the trench 580.

The outer bank 516′ can be disposed on the low potential power line 535. The outer bank 516′ can cover an outer portion of the low potential power line 535 in an island shape. For example, the outer bank 516′ can cover a tapered portion of the low potential power line 535 and the planarization layer 515.

The outer bank 516′ can be disposed on the same layer as the bank 516 to be formed of the same material as the bank 516. At this time, the bank 516 and the outer bank 516′ can be separated on both sides with respect to the trench 580, and a part of a top surface of the low potential power line 535 can be exposed without being covered by the outer bank 516′. Accordingly, the water transfer velocity (WTV) can be suppressed.

The cathode 533 can extend into the trench 580 in the display area AA. The cathode 533 can extend into the trench 580 and can be in contact with a top surface of the low potential power line 535 exposed in the trench 580 and receive low potential power from the low potential power line 535.

The protective layer 540 can extend into the trench 580 to cover the cathode 533. For example, except for the non-display area NA on the second side, the protective layer 540 can be disposed to surround the cathode 533. In contrast, in the non-display area NA on the second side, the protective layer 540 can cover a part of the top surface of the cathode 533.

The transparent layer 571 of the adhesive layer 570 can cover the trench 580. For example, the transparent layer 571 can extend to the trench 580 to cover the protective layer 540, the low potential power line 535, and the outer bank 516′.

In the display device 500 according to another example embodiment of the present disclosure, as a moisture adsorbent for adsorbing or removing moisture or oxygen, a plurality of core-shell particles 172a-3 made of reduced metal oxide is used. For example, titanium oxide (TiO₂) comprising oxygen vacancy is used as the shell layer 172a-3s of a plurality of core-shell particles 172a-3c, and silicon oxide (SiO₂) having low cost and high adhesion to the shell layer 172a-3s is used as the core particles 172a-3c. Accordingly, a dark spot defect of the display device 500 due to moisture permeation can be delayed by using a plurality of low-cost core-shell particles 172a-3.

Further, in the display device 500 according to still another example embodiment of the present disclosure, since titanium oxide (TiO₂) having a small particle size is used as the shell layer 172a-3s of the core-shell particles 172a-3, an excessive increase in size due to the aggregation phenomenon of the core-shell particles 172a-3 can be prevented, thereby improving the reliability of the display device 500.

Further, in the display device 500 according to still another example embodiment of the present disclosure, the trench 580 is provided at the edge of the non-display area NA to minimize the effect of moisture permeation on the GIP circuit part 108. For example, in the display device 500 according to still another example embodiment of the present disclosure, the cathode 533 can extend into the trench 580 and can be in contact with the low potential power line 535 exposed in the trench 580. Accordingly, the entire GIP circuit part 108 and the display area AA can be sealed, and the moisture permeation effect can be minimized. Accordingly, the stability and durability of the GIP circuit part 108 can be remarkably improved, and the reliability of the display device 500 can be improved.

The example embodiments of the present disclosure can also be described as follows:

According to an embodiment of the present disclosure, a display device includes a first substrate including a display area and a non-display area outside the display area, a plurality of light emitting elements disposed on the first substrate, an adhesive layer disposed on the plurality of light emitting elements and including a plurality of core-shell particles, and a second substrate disposed on the adhesive layer, and the plurality of core-shell particles can include reduced titanium oxide (TiO₂₋ₓ).

According to another aspect of the present disclosure, each of the plurality of core-shell particles can include core particles including silicon oxide (SiO₂), and a shell layer surrounding the core particles and including reduced titanium oxide.

According to yet another aspect of the present disclosure, a plurality of core-shell particles can be disposed so as to correspond to the entire surface of the first substrate.

According to yet another aspect of the present disclosure, a plurality of core-shell particles can be disposed so as to correspond to the outer area of the first substrate.

According to yet another aspect of the present disclosure, the display device can further include an insulating layer and a planarization layer disposed above the first substrate and extending from the display area to the non-display area, and at least one trench disposed in the non-display area and in which at least one of the insulating layer and the planarization layer is removed, and the adhesive layer can cover the trench.

According to yet another aspect of the present disclosure, the adhesive layer can include a transparent layer disposed on the plurality of light emitting elements, and an adsorption layer disposed on the transparent layer and including a plurality of core-shell particles.

According to yet another aspect of the present disclosure, the adhesive layer can further include a plurality of nickel particles and a plurality of calcium oxide particles.

A display device according to another example embodiment of the present disclosure can include a first substrate including a display area and a non-display area outside the display area, a plurality of light emitting elements disposed on the first substrate, an adsorption layer disposed on the plurality of light emitting elements and including a plurality of core-shell particles, and a second substrate disposed on the adsorption layer. Each of the plurality of core-shell particles can include a core particle made of silicon oxide and a shell layer surrounding the core particle and including oxygen vacancy.

According to another aspect of the present disclosure, a plurality of core-shell particles can be disposed so as to correspond to the entire surface of the adsorption layer.

According to yet another aspect of the present disclosure, the adsorption layer can include a central portion and an outer portion surrounding the central portion, and the plurality of core-shell particles can be disposed in the central portion and the outer portion or only in the outer portion among the central portion and the outer portion.

According to yet another aspect of the present disclosure, the display device can further include an insulating layer and a planarization layer disposed above the first substrate and extending from the display area to the non-display area, at least one trench disposed in the non-display area and in which at least one layer of the insulating layer and the planarization layer is removed, and a transparent layer disposed between the plurality of light emitting elements and the adsorption layer, the transparent layer can cover the trench.

According to yet another aspect of the present disclosure, the shell layer can be formed of one or more materials of titanium (Ti), chromium (Cr), vanadium (V), manganese (Mn), zirconium (Zr), niobium (Nb), molybdenum (Mo), technetium (Tc), ruthenium (Ru), rhodium (Rh), and palladium (Pd).

Although the example embodiments of the present disclosure have been described in detail with reference to the accompanying drawings, the present disclosure is not limited thereto and can be embodied in various forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all embodiments and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate including a display area and a non-display area outside the display area;
a plurality of light emitting elements disposed on the first substrate;
an adhesive layer disposed on the plurality of light emitting elements and including a plurality of core-shell particles; and
a second substrate disposed on the adhesive layer,
wherein the plurality of core-shell particles includes reduced titanium oxide (TiO₂₋ₓ1).

2. The display device according to claim 1, wherein each of the plurality of core-shell particles includes:
core particles including silicon oxide (SiO₂); and
a shell layer surrounding the core particles and including the reduced titanium oxide.

3. The display device according to claim 1, wherein the plurality of core-shell particles is disposed so as to correspond to an entire surface of the first substrate.

4. The display device according to claim 1, wherein the plurality of core-shell particles is disposed so as to correspond to an outer peripheral area of the first substrate.

5. The display device according to claim 1, further comprising:
an insulating layer and a planarization layer disposed on the first substrate and extending from the display area to the non-display area; and
at least one trench disposed in the non-display area and in which at least one of the insulating layer and the planarization layer is removed.

6. The display device according to claim 5, wherein the adhesive layer covers the at least one trench in the non-display area.

7. The display device according to claim 6, further comprising:
a low potential power line disposed in the least one trench below the adhesive layer in the non-display area.

8. The display device according to claim 7, further comprising:
an outer bank disposed on the low potential power line in the non-display area and covering an outer portion of the low potential power line.

9. The display device according to claim 1, wherein the adhesive layer includes:
a transparent layer disposed on the plurality of light emitting elements; and
an adsorption layer disposed on the transparent layer and including the plurality of core-shell particles.

10. The display device according to claim 9, wherein the adhesive layer further includes a plurality of nickel particles and a plurality of calcium oxide particles.

11. The display device according to claim 9, further comprising:
an insulating layer and a planarization layer disposed on the first substrate and extending from the display area to the non-display area; and
at least one trench disposed in the non-display area and in which at least one of the insulating layer and the planarization layer is removed,
wherein the transparent layer of the adhesive layer is disposed in the at least one trench.

12. A display device, comprising:
a first substrate including a display area and a non-display area outside the display area;
a plurality of light emitting elements disposed on the first substrate;
an adsorption layer disposed on the plurality of light emitting elements and including a plurality of core-shell particles; and
a second substrate disposed on the adsorption layer,
wherein each of the plurality of core-shell particles includes:
a core particle made of silicon oxide, and
a shell layer surrounding the core particle and including oxygen vacancy.

13. The display device according to claim 12, wherein the plurality of core-shell particles is disposed so as to correspond to an entire surface of the adsorption layer.

14. The display device according to claim 12, wherein the adsorption layer includes a central portion and an outer portion surrounding the central portion, and
wherein the plurality of core-shell particles is disposed only in the outer portion, among the central portion and the outer portion.

15. The display device according to claim 12, further comprising:
an insulating layer and a planarization layer disposed on the first substrate and extending from the display area to the non-display area;
at least one trench disposed in the non-display area and in which at least one of the insulating layer and the planarization layer is removed; and
a transparent layer disposed between the plurality of light emitting elements and the adsorption layer.

16. The display device according to claim 15, wherein the transparent layer covers the at least one trench.

17. The display device according to claim 12, wherein the shell layer includes one or more materials among titanium (Ti), chromium (Cr), vanadium (V), manganese (Mn), zirconium (Zr), niobium (Nb), molybdenum (Mo), technetium (Tc), ruthenium (Ru), rhodium (Rh), and palladium (Pd).

18. The display device according to claim 12, wherein the adsorption layer includes a plurality of nickel particles and a plurality of calcium oxide particles.
